(19) United States
(12) Patent Application Publication
(10) Pub. No.: US 2013/0020652 A1
(43) Pub. Date: Jan. 24, 2013

(54) METHOD FOR SUPPRESSING SHORT CHANNEL EFFECT OF CMOS DEVICE

(71) Applicants: Xiaolu HUANG, Shanghai (CN); Gang MAO, Shanghai (CN); Yuwen CHEN, Shanghai (CN); Tzuyin CHIU, Shanghai (CN)

(72) Inventors: Xiaolu HUANG, Shanghai (CN); Gang MAO, Shanghai (CN); Yuwen CHEN, Shanghai (CN); Tzuyin CHIU, Shanghai (CN)

(73) Assignee: SHANGHAI HUALI MICROELECTRONICS CORPORATION, Shanghai (CN)

(21) Appl. No.: 13/339,429

(22) Filed: Dec. 29, 2011

(30) Foreign Application Priority Data
Jul. 22, 2011 (CN) 201110206463.X
Jul. 22, 2011 (CN) 201110206500.7

(51) Int. Cl. H01L 21/266; H01L 27/092

(52) U.S. Cl. 257/369; 438/527; 257/E27.062; 257/E21.346

(57) ABSTRACT

A method for manufacturing a gate-last high-K CMOS structure comprising a first transistor and a second transistor, which is formed in a Si substrate includes: implanting acceptor impurity into a gate recess of the first transistor to form a first buried-layer heavily doping region under a channel of the first transistor; and implanting donor impurity into a gate recess of the second transistor to form a second buried-layer heavily doping region under a channel of the second transistor.

### CROSS REFERENCE TO RELATED APPLICATIONS

This application is based upon and claims the benefit of priority from the prior Chinese Patent Application No. 201110206500.7 filed on Jul. 22, 2011, entitled “METHOD FOR SUPPRESSING SHORT CHANNEL EFFECT OF CMOS DEVICE”, and the prior Chinese Patent Application No. 201110206463.X filed on Jul. 22, 2011, entitled “METHOD FOR MANUFACTURING CMOS STRUCTURE BY SELF-ALIGNING CHANNEL DOPING TO SUPPRESS SHORT CHANNEL EFFECT OF THE CMOS STRUCTURE”, with Chinese State Intellectual Property Office, under 35 U.S.C. §119. The content of the above prior Chinese Patent Applications is incorporated herein by reference in its entirety.

### FIELD OF THE INVENTION

The present application relates to a semiconductor manufacturing process, and particularly to a method for suppressing Short Channel Effect of a Complementary Metal Oxide Semiconductor (CMOS) device and a CMOS device manufactured by the method.

### BACKGROUND OF THE INVENTION

In the process of manufacturing a semiconductor device, as the integrating density of a semiconductor integrated circuit becomes higher and higher, the semiconductor device becomes smaller and smaller, and the channel of a CMOS device also becomes shorter. Therefore a proportion of charge in channel depletion regions, which is shared by a source-substrate PN junction formed between a source region and a substrate of a MOS transistor and a drain-substrate PN junction formed between a drain region and the substrate of the MOS transistor, to the total charge of the channel increases, and as a result, the gate-controlling ability reduces, and Short Channel Effect (SCE) occurs.

Short Channel Effect is a phenomenon occurring when a channel length of a CMOS device becomes short, which results in many undesirable effects, such as threshold voltage shift, source-drain breakdown, drain induction barrier lower in a higher drain voltage, and so on, and even seriously results in invalid performance of the CMOS device.

An equation of threshold voltage shift is conducted according to a charge share model proposed by Yau, as follows:

$$Δ {V}_{th , l} = {V}_{th} ( long channel ) - {V}_{th} ( short channel ) = \frac{Δ {Q}_{l}}{{C}_{ox}} = \frac{{Q}_{b}}{{C}_{ox}} \times \frac{{X}_{j}}{L} \sqrt{1 + \frac{2 {X}_{dm}}{{X}_{d}}} -$$

Short Channel Effect can be suppressed by respectively adjusting three parameters, i.e. a capacitor Cₒₓ of oxidation layer per unit area, a width X_{dm} of depletion layer in channel region, and a junction depth Xⱼ of a source-substrate PN junction and a drain-substrate PN junction in the above equation, that is, by increasing the value of Cₒₓ (or correspondingly reducing the depth tₒₓ of oxidation layer), reducing X_{dm}, and reducing Xⱼ of the source-substrate PN junction and the drain-substrate PN junction. As shown in FIG. 1, as for the adjustment of X_{dm}, that is, the adjustment of channel doping concentration Nb, in a conventional method, a buried-layer heavily doping is performed under a channel. Since the buried-layer heavily doping is performed to the whole active region, the source region and the drain region may also be subject to this doping. Because this impurity type is opposite to the original doping type of the source and the drain, the following side effects will be caused: 1. the source and drain doping will be compensated for, thereby the parasitic resistance of the source and drain will increase; 2. profiles of the source-substrate PN junction and the drain-substrate PN junction may be affected, thereby their reverse leakage current will increase; 3. the junction depth Xⱼ of the source-substrate PN junction and the drain-substrate PN junction may increase, thereby causing a reverse affect on SCE suppressing.

### SUMMARY OF THE INVENTION

The present application provides a method for manufacturing a gate-last high-K CMOS structure which comprises a first transistor and a second transistor and is formed in a Si substrate by a gate last process, the method comprising the following steps: step a: removing dummy gates from the inside of a first transistor gate recess of the first transistor and a second transistor gate recess of the second transistor, and reserving thin oxidation layers respectively inside the first transistor gate recess and the second transistor gate recess during the removal of the dummy gates from the first transistor gate recess and the second transistor gate recess; step b: spin-coating a photo resist on the first transistor and the second transistor so as to fill the first transistor gate recess and the second transistor gate recess; step c: performing a photolithography so as to remove the photo resist on the first transistor and the photo resist inside the first transistor gate recess; step d: implanting acceptor impurity ions into the first transistor gate recess, so that a first buried-layer heavily doped region is formed under a channel of the first transistor; step e: removing the photo resist on the second transistor and inside the second transistor gate recess; step f: spin-coating the photo resist on the first transistor and the second transistor again, so as to fill the first transistor gate recess and the second transistor gate recess; step g: performing the photolithography again so as to remove the photo resist on the second transistor and the photo resist inside the second transistor gate recess; step h: implanting donor impurity ions into the second transistor gate recess, so that a second buried-layer heavily doped region is formed under a channel of the second transistor; step i: removing the photo resist on the first transistor and inside the first transistor gate recess; step j: performing an anneal so as to activate the implanted ions; and step k: performing next processes manufacturing a gate-last high-K device.

The present application further provides a method for suppressing Short Channel Effect of a CMOS structure which is formed by a gate-last high-K metal gate process and comprises at least a first semiconductor structure and a second semiconductor structure, wherein gate recesses respectively included in the first semiconductor and the second semiconductor are filled with dummy gates, and thin oxidation layers are reserved at the bottom of the gate recesses after the dummy gates are etched back, the method comprising the following steps: step S1: spin-coating a photo resist on the CMOS structure, and performing an exposure and development process to remove the photo resist on the region of the first semiconductor structure, so that a first photo resist is formed; step S2: performing an angle tilt ion implantation process in the gate recess exposed in the first photo resist; step S3: removing the first photo resist, spin-coating the photo resist on the CMOS structure again, and performing an exposure and development process to remove the photo resist on the region of the second semiconductor, so that a second photo resist is formed; step S4: performing the angle tilt ion implantation process in the gate recess exposed in the second photo resist; step S5: removing the second photo resist and activating the implanted ions.

The present application further provides a gate-last high-K CMOS structure, the CMOS structure comprising at least a first semiconductor structure and a second semiconductor structure, wherein the first semiconductor and the second semiconductor structures respectively include a gate recess, and a buried-layer heavily doped region is formed in a channel only under the gate recess respectively included in the first semiconductor structure and the second semiconductor structure.

The method for manufacturing a gate-last high-K CMOS structure by self-aligning channel doping to suppress Short Channel Effect of the CMOS structure according to the present application can solve the following problems existing in the related art: 1. the source and drain doping may be compensated for, thereby the parasitic resistance of the source and drain may increase; 2. profiles of the source-substrate PN junction and the drain-substrate PN junction may be affected, thereby the reverse leakage current may increase; 3. the junction depth Xⱼ of a source-substrate PN junction and a drain-substrate PN junction may be increased, thereby causing a reverse affect on SCE suppressing. However, the present application realizes a self-aligned channel doping of a CMOS device, a heavily doped buried-layer under the channel is formed whereas the source and drain region are not affected, thereby Short Channel Effect is effectively suppressed and the performance of the device is improved.

According to the method for suppressing Short Channel Effect of a CMOS device of the present application, since heavily doped buried-layers in the vicinity of the source region and the drain region under a channel are formed, or a heavily doped buried-layer in the vicinity of the drain region under the channel is solely formed, a self-aligned doping process is employed, and the source and drain region are not affected, so that Short Channel Effect can be effectively suppressed. The processes are simple and are easy to be achieved and operated.

### BRIEF DESCRIPTION OF THE DRAWINGS

The foregoing and further features, profiles, and advantages of the present application will become apparent and distinct from the following description of example embodiments with reference to the accompanying drawings. Like numerals are used to represent like parts throughout the drawings. The drawings are not in real scale, but only for the purpose of exemplarily illustrating the substance of the present application.

FIG. 1 is a schematic diagram of X_{dm} in the related art;

FIG. 2 is a structural diagram showing a CMOS structure formed after step a in the method for manufacturing a gate-last high-K CMOS structure by self-aligning channel doping to suppress Short Channel Effect of the CMOS structure is finished, according to the present application;

FIG. 3 is a structural diagram showing a CMOS structure formed after step c in the method for manufacturing a gate-last high-K CMOS structure by self-aligning channel doping to suppress Short Channel Effect of the CMOS structure is finished, according to the present application;

FIG. 4 is a structural diagram showing a CMOS structure formed after step g in the method for manufacturing a gate-last high-K CMOS structure by self-aligning channel doping to suppress Short Channel Effect of the CMOS structure is finished, according to the present application;

FIG. 5 is a structural diagram showing a CMOS structure formed after step j in the method for manufacturing a gate-last high-K CMOS structure by self-aligning channel doping to suppress Short Channel Effect of the CMOS structure is finished, according to the present application;

FIG. 6 is a structural diagram showing a CMOS structure formed after step k in the method for manufacturing a gate-last high-K CMOS structure by self-aligning channel doping to suppress Short Channel Effect of the CMOS structure is finished, according to the present application;

FIGS. 7-12 are flowcharts according to a second embodiment of the present application; and

FIGS. 13-18 are flowcharts according to a third embodiment of the present application.

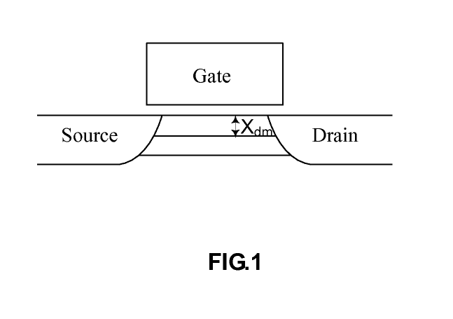

### DETAILED DESCRIPTION OF THE EMBODIMENTS

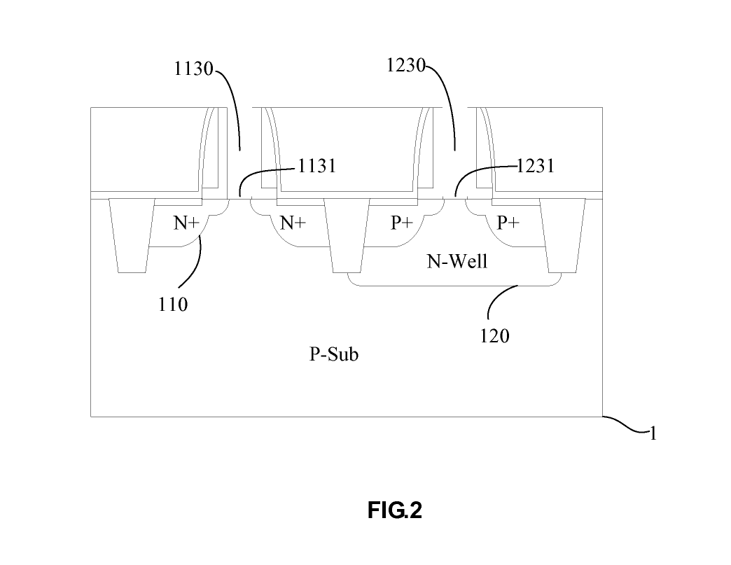

The embodiments of the present application will be further explained with reference to the accompanying drawings in FIGS. 2-18.

### A First Embodiment

The first embodiment illustrates the method for manufacturing a gate-last high-K CMOS structure by self-aligning channel doping to suppress Short Channel Effect of the CMOS structure according to the present application.

Firstly, a CMOS structure 1 is formed on a Si substrate by a gate-last high-K metal-gate (HKMG) process and comprises a first transistor 110 and a second transistor 120, wherein the substrate is provided as a P-type Si substrate.

Further, the first transistor 110 is provided as a NMOS transistor, and the second transistor 120 is provided as a PMOS transistor.

FIG. 2 is a structural diagram showing a CMOS structure formed after step a in the method for manufacturing a gate-last high-K CMOS structure by self-aligning channel doping to suppress Short Channel Effect of the CMOS structure is finished, according to the present application. Referring to FIG. 2, step a: dummy gates in a first transistor gate recess 1130 of the first transistor 110 device and a second transistor gate recess 1230 of the second transistor 120 device are removed.

In the step a, an etching process is performed, so as to remove the dummy gates from the first transistor gate recess 1130 and the second transistor gate recess 1230.

Further, thin oxidation layers are reserved during the removal of the dummy gates from the first transistor gate recess 1130 and the second transistor gate recess 1230 in the step a, that is, a thin oxidation layer 1131 located at the bottom of the first transistor gate recess 1130 and a thin oxidation layer 1231 located at the bottom of the second transistor gate recess 1230 are reserved.

Step b: a photo resist is spin-coated on the first transistor 110 and the second transistor 120, so as to fill the first transistor gate recess 1130 and the second transistor gate recess 1230.

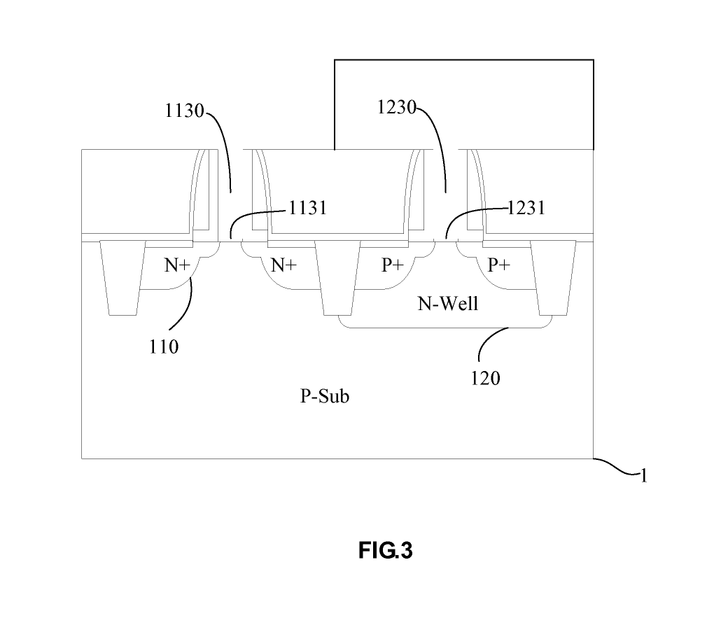

FIG. 3 is a structural diagram showing a CMOS structure formed after step c in the method for manufacturing a gate-last high-K CMOS structure by self-aligning channel doping to suppress Short Channel Effect of the CMOS structure is finished, according to the present application. Referring to FIG. 3, step c: a photolithography is performed, so as to remove the photo resist on the first transistor 110 device and the photo resist inside the first transistor gate recess 1130.

Step d: acceptor impurity is implanted into the first transistor gate recess 1130 (for example, in a manner of performing the implantation perpendicularly to the upper surface of the substrate 1), so that a first buried-layer heavily doped region 111 is formed under the channel of the first transistor 110. Since the first buried-layer heavily doped region 111 is formed only under the channel of the first transistor 110, the source region and the drain region are not affected, Short Channel Effect is effectively suppressed.

Further, such as B, BF₂, BF, In or the like based ions are implanted as acceptor impurity, so that the first buried-layer heavily doped region 111 is formed under the NMOS channel whereas the source region and the drain region are not affected.

Step e: the photo resist is removed, that is, the residual photo resist on the second transistor 120 and the residual photo resist inside the second transistor gate recess 1230 are removed.

Step f: a photo resist is spin-coated on the first transistor 110 and the second transistor 120 again, so as to fill the first transistor gate recess 1130 and the second transistor gate recess 1230.

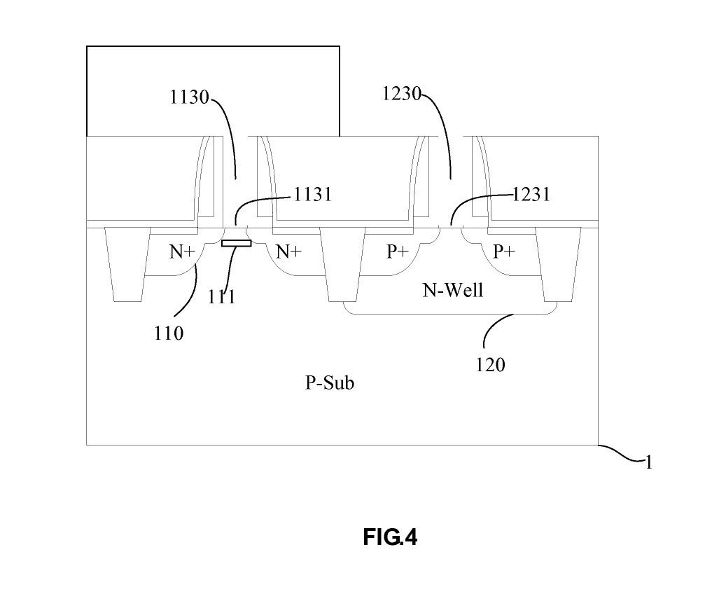

FIG. 4 is a structural diagram showing a CMOS structure formed after step g in the method for manufacturing a gate-last high-K CMOS structure by self-aligning channel doping to suppress Short Channel Effect of the CMOS structure is finished, according to the present application. Referring to FIG. 4, step g: the photolithography is performed again, so as to remove the photo resist on the second transistor 120 device and the photo resist inside the second transistor gate recess 1230.

Step h: donor impurity is implanted into the second transistor gate recess 1230 (for example, in a manner of performing the implantation perpendicularly to the upper surface of the substrate 1), so that a second buried-layer heavily doped region 121 is formed under the channel of the second transistor 120. Since the second buried-layer heavily doped region 121 is formed only under the channel of the second transistor 120, the source region and the drain region are not affected, Short Channel Effect is effectively suppressed.

In the step h, such as P, As or the like based ions are implanted as the donor impurity, so that the second buried-layer heavily doped region 121 is formed under the PMOS channel whereas the source region and the drain region are not affected.

Step i: the photo resist is removed again, that is, the residual photo resist covering the first transistor 110 and the residual photo resist inside the first transistor gate recess 1130 are removed.

In the present embodiment, the process sequence of the ion implantation process steps b-e regarding the NMOS structure 110 and the ion implantation process steps f-i regarding the PMOS structure 120 can be interchanged.

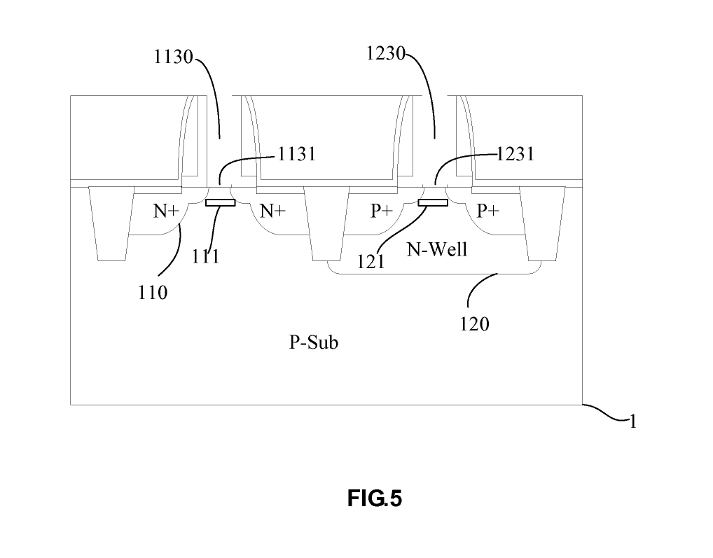

FIG. 5 is a structural diagram showing a CMOS structure formed after step j in the method for manufacturing a gate-last high-K CMOS structure by self-aligning channel doping to suppress Short Channel Effect of the CMOS structure is finished, according to the present application. Referring to FIG. 5, step j: an anneal process is performed so as to activate the ions implanted into the first buried-layer heavily doped region 111 under the first transistor gate recess 1130 and the second buried-layer heavily doped region 121 under the second transistor gate recess 1230.

In the step j, the anneal process, such as Rapid Thermal Process (RTP), Spike Anneal, Flash Anneal and so on, may be performed to activate the implanted ions.

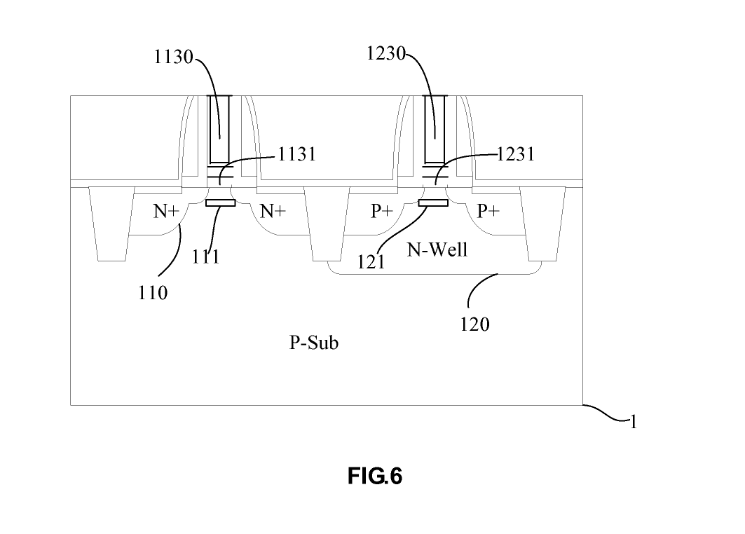

FIG. 6 is a structural diagram showing a CMOS structure formed after step k in the method for manufacturing a gate-last high-K CMOS structure by self-aligning channel doping to suppress Short Channel Effect of the CMOS structure is finished, according to the present application. Referring to FIG. 6, step k: next processes manufacturing a gate-last high-K device are performed. Since these next processes are the same as those in the related art, the description thereof is omitted.

### A Second Embodiment

SCE is caused mainly in that charge in channel depletion regions are shared by a source-substrate PN junction and a drain-substrate PN junction respectively in the vicinity of the source region and the drain region under the channel, therefore, the present embodiment mainly aims at the adjustment of the vicinity of the source region and the drain region.

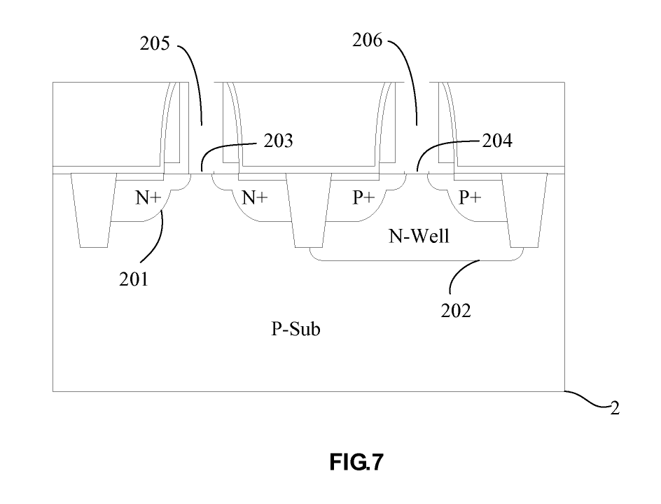

As shown in FIGS. 7-12, the second embodiment illustrates a method for suppressing Short Channel Effect of a CMOS structure, wherein the CMOS structure 2 manufactured by a gate-last high-K metal gate process comprises a NMOS structure 201 and a PMOS structure 202, and a gate recess 205 included in the NMOS structure 201 and a gate recess 206 included in the PMOS structure 202 are respectively filled with a dummy gate. After the dummy gates are etched back, thin oxidation layers 203 and 204 respectively remain at the bottom of the gate recesses 205 and 206, as shown in FIG. 7.

The method for suppressing Short Channel Effect of a CMOS structure according to the present embodiment comprises the following steps:

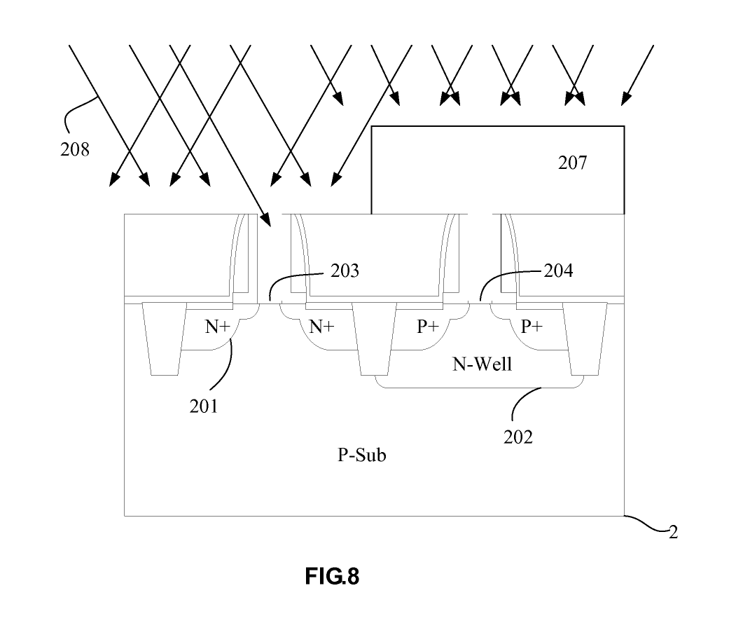

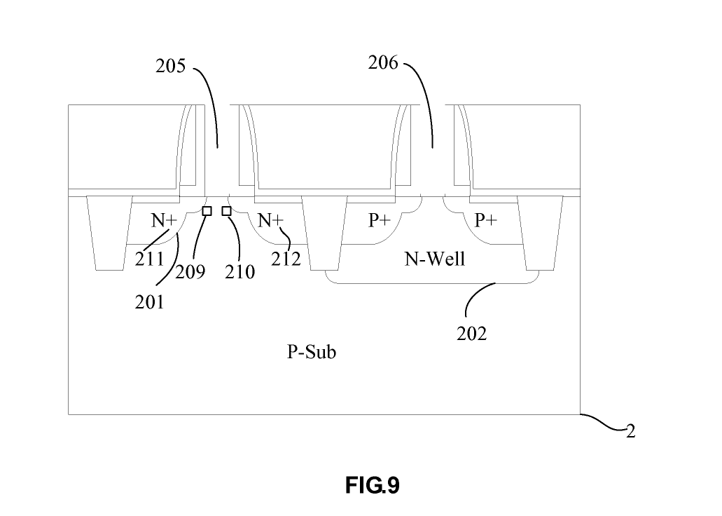

Firstly, a photo resist is spin-coated in the CMOS structure 2, and an exposure and development process is performed, so that the photo resist on the NMOS structure 201 region is removed, and so that a first photo resist 207 only covering the PMOS structure 202 is formed, and an angle tilt ion implantation process 208 is performed so as to bi-directionally implant acceptor impurity ions (such as B, BF₂, BF, In or the like based ions by 180° angle turn, as shown in FIG. 8. Buried-layer heavily regions 209 and 210 are respectively formed in the channel of the NMOS structure 201 only in the vicinity of its source region 211 and its drain region 212, as shown in FIG. 9. Since a self-aligned doping process is employed, the source region 211 and the drain region 212 are not affected during the angle tilt ion implantation process 208.

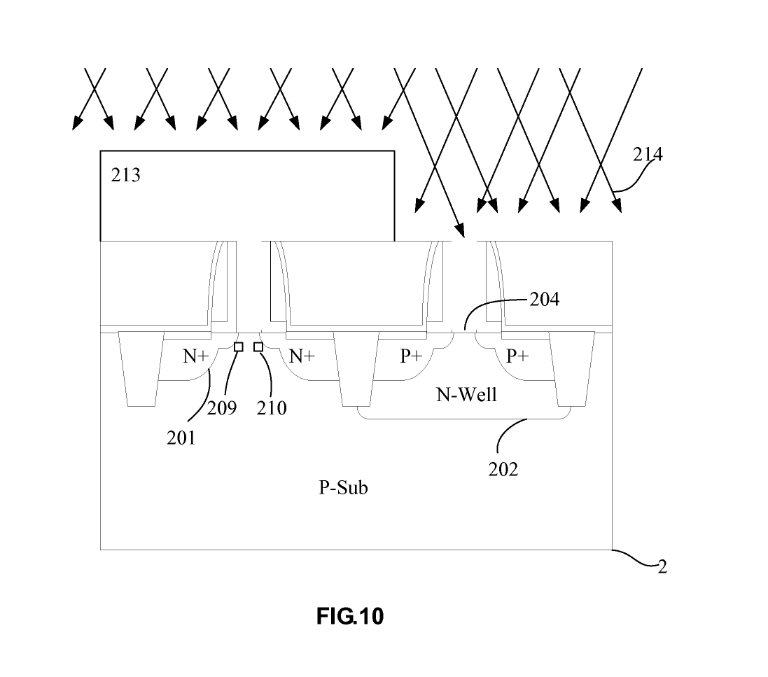

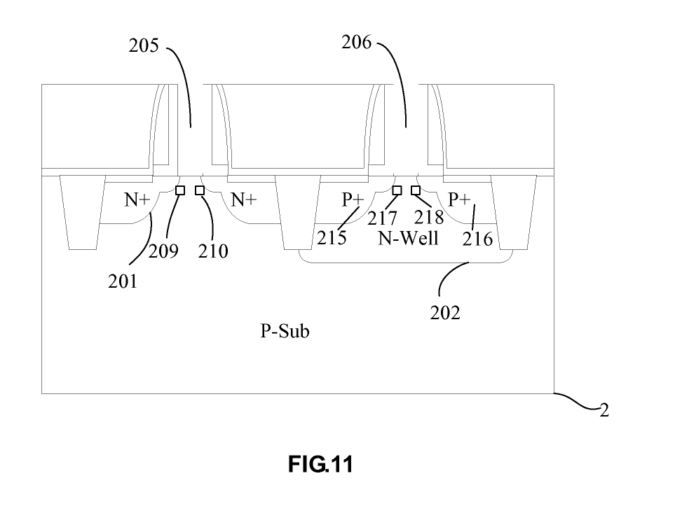

After the first photo resist 207 is removed, the photo resist is spin-coated in the CMOS structure 2 again, and an exposure and development process is performed, so that the photo resist on the PMOS structure 202 region is removed, and so that a second photo resist 213 only covering the NMOS structure 201 is formed, and an angle tilt ion implantation process 214 is performed so as to bi-directionally implant donor impurity ions (such as P, As or the like based ions) by 180° angle turn, as shown in FIG. 10. Buried-layer heavily regions 217 and 218 are respectively formed in the channel of the PMOS structure 202 only in the vicinity of its source region 215 and its drain region 216, as shown in FIG. 11. Since the self-aligned doping process is employed, the source region 215 and the drain region 216 are not affected during the angle tilt ion implantation process 214.

Thereafter, the second photo resist 213 is removed.

In the present embodiment, the process sequence of the angled tilt ion implantation processes 208 and 214 respectively regarding the NMOS structure 201 and the PMOS structure 202 can be interchanged.

Then, Rapid Thermal Process, Spike Anneal or Flash Anneal for the CMOS structure 2 may be performed to activate the implanted ions.

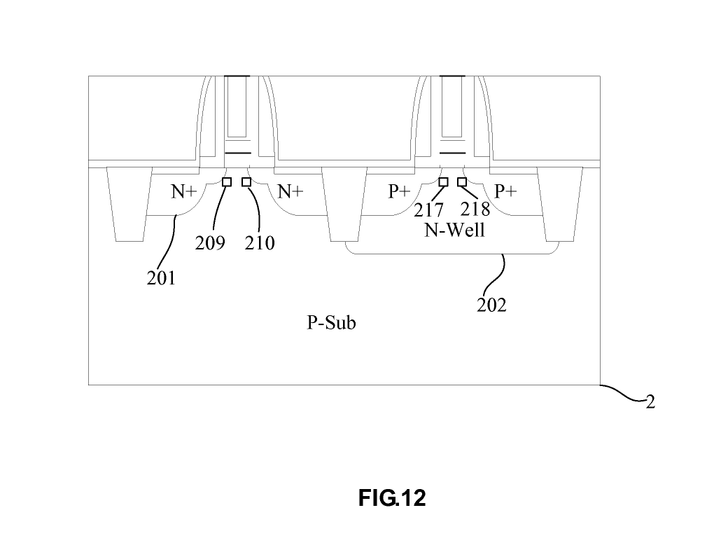

Finally, the next processes manufacturing a gate-last high-K metal gate are performed so as to finish the manufacture of the CMOS device, as shown in FIG. 12. Since these next processes are the same as those in the related art, the description thereof is omitted.

### A Third Embodiment

SCE is caused mainly in that the charge in channel depletion regions is shared by a source-substrate PN junction and a drain-substrate PN junction respectively in the vicinity of the source region and the drain region under the channel, and electric shift is caused substantially by the shared charge in the vicinity of the drain region under the channel. Therefore, the present embodiment mainly aims at the adjustment of the vicinity of the drain region.

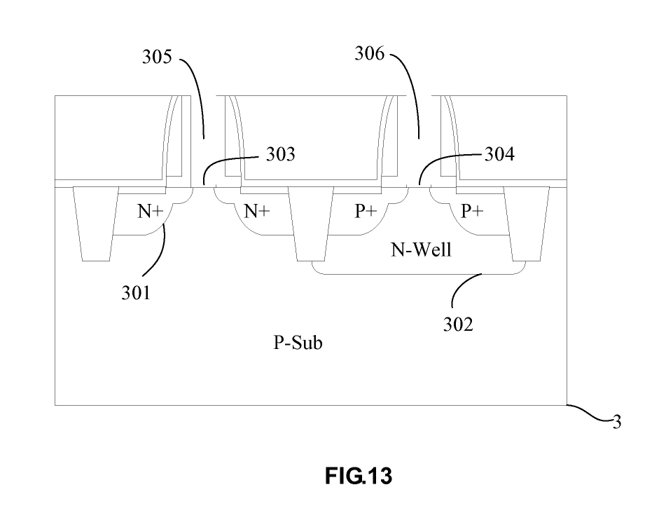

As shown in FIGS. 13-18, the third embodiment illustrates a method for suppressing Short Channel Effect of a CMOS structure, wherein the CMOS structure 3 manufactured by a gate-last high-K metal gate process comprises a NMOS structure 301 and a PMOS structure 302, wherein a gate recess 305 included in the NMOS structure 301 and a gate recess 306 included in the PMOS structure 302 are filled with dummy gates. After the dummy gates are etched back, thin oxidation layers 303 and 304 remain at the bottom of the gate recesses 305 and 306, as shown in FIG. 13.

The method for suppressing Short Channel Effect of a CMOS structure according to the present embodiment comprises the following steps:

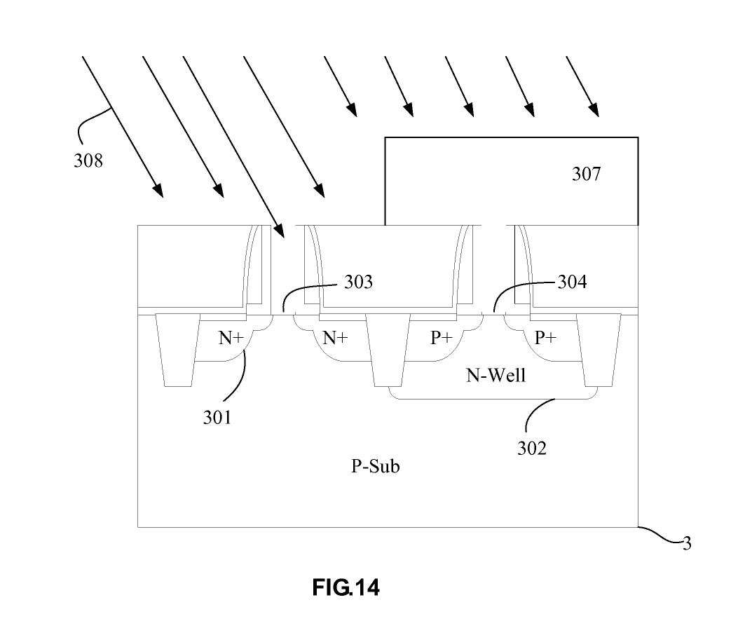

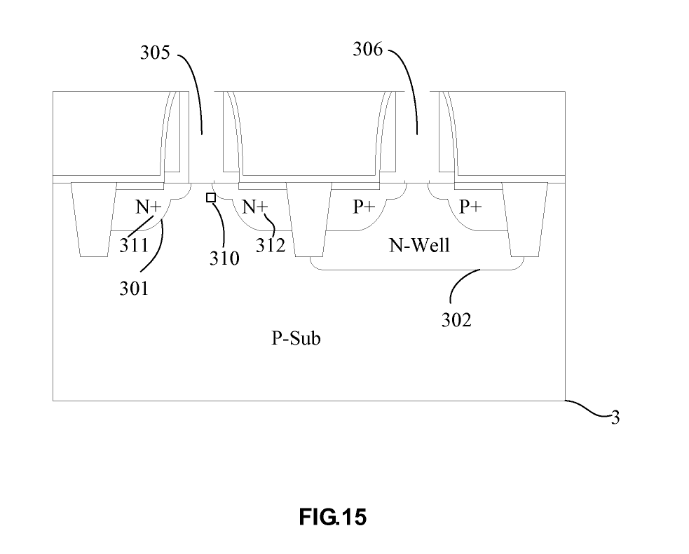

Firstly, a photo resist is spin-coated in the CMOS structure 3, and an exposure and development process is performed, so that the photo resist on the NMOS structure 301 region is removed, and so that a first photo resist 307 only covering the PMOS structure 302 is formed, and an angle tilt ion implantation process 308 is performed so as to implant acceptor impurity ions (such as B, BF₂, BF, In or the like based ions) in one direction, as shown in FIG. 14. A buried-layer heavily region 310 is formed in the channel of the NMOS structure 301 only in the vicinity of its drain region 312, as shown in FIG. 15. Since a self-aligned doping process is employed, the source region 311 and the drain region 312 are not affected during the angle tilt ion implantation process 308.

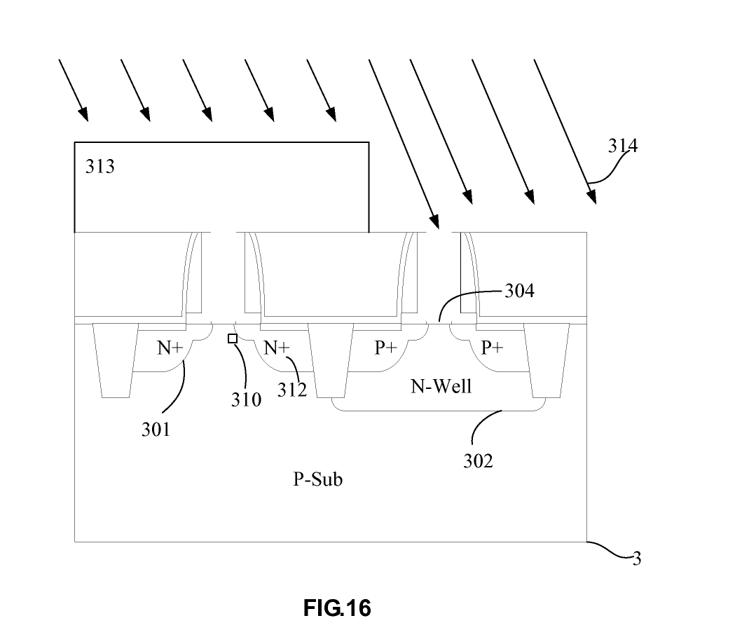

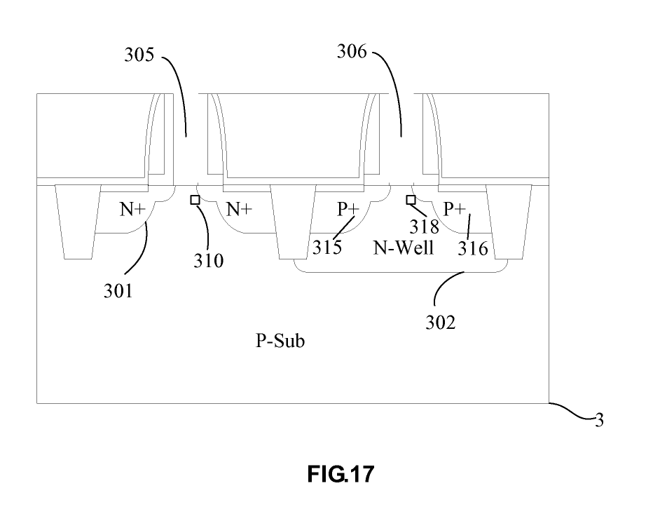

After the first photo resist 307 is removed, the photo resist is spin-coated in the CMOS structure 3 again, and an exposure and development process is performed, so that the photo resist on the PMOS structure 302 region is removed, and so that a second photo resist 313 only covering the NMOS structure 301 is formed, and an angle tilt ion implantation process 314 is performed so as to implant donor impurity ions (such as P, As or the like based ions) in one direction, as shown in FIG. 16. A buried-layer heavily regions 318 is formed in the channel of the PMOS structure 302 only in the vicinity of its drain region 316, as shown in FIG. 17. Since a self-aligned doping process is employed, the source region 315 and the drain region 316 are affected during the angle tilt ion implantation process 314.

Thereafter, the second photo resist 313 is removed.

In the present embodiment, the process sequence of the angled tilt ion implantation processes 308 and 314 respectively regarding the NMOS structure 301 and the PMOS structure 302 can be interchanged.

Then, Rapid Thermal Process, Spike Anneal or Flash Anneal for the CMOS structure 3 may be performed to activate the implanted ions.

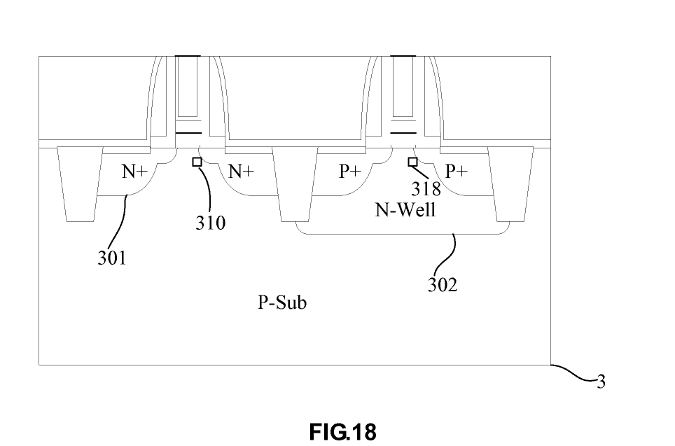

Finally, the next processes manufacturing a gate-last high-K metal gate are performed so as to finish the manufacture of the CMOS device, as shown in FIG. 18. Since these sequence processes are the same as those in the related art, the description thereof is omitted.

According to the above embodiments, the method for manufacturing a gate-last high-K CMOS structure by self-aligning channel doping to suppress Short Channel Effect of the CMOS structure according to the present application can solve the following problems existing in the related art: 1. the source and drain doping may be compensated for, thereby the parasitic resistance of the source and drain may increase; 2. profiles of the source-substrate PN junction and the drain-substrate PN junction may be affected, thereby the reverse leakage current may increase; 3. the junction depth Xj of the source-substrate PN junction and the drain-substrate PN junction may be increased, thereby causing a reverse affect on SCE suppressing. However, the present application realizes a self-aligned channel doping of a CMOS device, a heavily doped buried-layer under the channel is formed whereas the source and drain region are not affected, thereby Short Channel Effect is effectively suppressed and the performance of the device is improved.

According to the method for suppressing Short Channel Effect of a CMOS device of the present application, since heavily doped buried-layers in the vicinity of the source region and the drain region under the channel are formed, or a heavily doped buried-layer in the vicinity of the drain region under the channel is solely formed, a self-aligned doping process is employed, and the source and drain region are not affected, so that Short Channel Effect is effectively suppressed. The processes are simple and are easy to be achieved and operated.

Although the present invention has been described with reference to the above-described embodiments, it is not limited to the above-described embodiments which are only exemplary. It should be understood by those skilled in the art that any equivalent modifications and substitution made to the present application may fall within the scope of the present application. Therefore, all variations and modifications implemented without departing from the spirit and essence of the present invention should be covered by the scope of the present invention.

What is claimed is:

1. A method for manufacturing a gate-last high-K CMOS structure which comprises a first transistor and a second transistor and is formed in a Si substrate by a gate last process, comprising the following steps:
step a: removing dummy gates respectively from the inside of a first transistor gate recess of the first transistor and a second transistor gate recess of the second transistor, and reserving thin oxidation layers respectively inside the first transistor gate recess and the second transistor gate recess during the removal of the dummy gates respectively from the first transistor gate recess and the second transistor gate recess;
step b: spin-coating a photo resist on the first transistor and the second transistor so as to fill the first transistor gate recess and the second transistor gate recess;
step c: performing a photolithography so as to remove the photo resist on the first transistor and the photo resist inside the first transistor gate recess;
step d: implanting acceptor impurity ions into the first transistor gate recess, so that a first buried-layer heavily doped region is formed under a channel of the first transistor;
step e: removing the photo resist on the second transistor and inside the second transistor gate recess;
step f: spin-coating the photo resist on the first transistor and the second transistor again, so as to fill the first transistor gate recess and the second transistor gate recess;
step g: performing the photolithography again so as to remove the photo resist on the second transistor and the photo resist inside the second transistor gate recess;
step h: implanting donor impurity ions into the second transistor gate recess, so that a second buried-layer heavily doped region is formed under a channel of the second transistor;
step i: removing the photo resist on the first transistor and inside the first transistor gate recess;
step j: performing an anneal so as to activate the implanted ions;
step k: performing next processes manufacturing a gate-last high-K device.

2. The method for manufacturing the gate-last high-K CMOS structure according to claim 1, wherein the Si substrate is provided as a P-type Si substrate.

3. The method for manufacturing the gate-last high-K CMOS structure according to claim 1, wherein the first transistor is provided as a NMOS transistor and the second transistor is provided as a PMOS transistor.

4. The method for manufacturing the gate-last high-K CMOS structure according to claim 1, wherein in the step a, an etching process is performed so as to remove the dummy gates respectively from the first transistor gate recess and the second transistor gate recess.

5. The method for manufacturing the gate-last high-K CMOS structure according to claim 1, wherein in the step d, B, BF₂, BF or In element based ions are implanted as the acceptor impurity ions.

6. The method for manufacturing the gate-last high-K CMOS structure according to claim 1, wherein in the step h, P or As element based ions are implanted as the donor impurity ions.

7. The method for manufacturing the gate-last high-K CMOS structure according to claim 1, wherein in the step j, Rapid Thermal Process, Spike Anneal or Flash Anneal is performed to activate the implanted ions.

8. A method for suppressing Short Channel Effect of a CMOS structure which is formed by a gate-last high-K metal gate process and comprises at least a first semiconductor structure and a second semiconductor structure, wherein gate recesses respectively included in the first semiconductor and the second semiconductor are respectively filled with dummy gates, and thin oxidation layers are reserved respectively at the bottom of the gate recesses after the dummy gates are respectively etched back, the method comprising the following steps:
step S1: spin-coating a photo resist on the CMOS structure, and performing an exposure and development process to remove the photo resist on the region of the first semiconductor structure, so that a first photo resist is formed;
step S2: performing an angle tilt ion implantation process in the gate recess exposed in the first photo resist;
step S3: removing the first photo resist, spin-coating a photo resist on the CMOS structure again, and performing an exposure and development process to remove the photo resist on the region of the second semiconductor, so that a second photo resist is formed;
step S4: performing the angle tilt ion implantation process in the gate recess exposed in the second photo resist;
step S5: removing the second photo resist and activating the implanted ions.

9. The method for suppressing Short Channel Effect of the CMOS structure according to claim 8, wherein the first semiconductor structure is a NMOS structure and the second semiconductor structure is a PMOS structure.

10. The method for suppressing Short Channel Effect of the CMOS structure according to claim 8, wherein in the steps S2 and S4, performing the angle tilt ion implantation process comprises: performing the ion implantation processes in channel regions respectively in the vicinity of drains of the first semiconductor structure and the second semiconductor structure, and forming buried-layer heavily doped regions in the channel respectively in the vicinity of the drains under the gate recesses respectively included in the first semiconductor structure and the second semiconductor structure.

11. The method for suppressing Short Channel Effect of the CMOS structure according to claim 8, wherein in the step S2, the implanted ions in the angle tilt ion implantation process are B, BF₂, BF or In element based acceptor impurity ions.

12. The method for suppressing Short Channel Effect of the CMOS structure according to claim 8, wherein in the step S4, the implanted ions in the angle tilt ion implantation process are P or As element based donor impurity ions.

13. The method for suppressing Short Channel Effect of the CMOS structure according to claim 8, wherein in the step S5, a Rapid Thermal Process, a Spike Anneal or a Flash Anneal process is performed to activating the implanted ions.

14. The method for suppressing Short Channel Effect of the CMOS structure according to claim 8, wherein in the steps S2 and S4, performing the angle tilt ion implantation processes comprises: performing the ion implantation processes in channel regions respectively in the vicinity of sources and drains of the first semiconductor structure and the second semiconductor structure, and forming buried-layer heavily doped regions in the channel regions respectively in the vicinity of the sources and the drains under the gate recesses respectively included in the first semiconductor structure and the second semiconductor structure.

15. A gate-last high-K CMOS structure, the CMOS structure comprising at least a first semiconductor structure and a second semiconductor structure, wherein the first semiconductor and the second semiconductor structures respectively include a gate recess, and a buried-layer heavily doped region is formed in a channel under the gate recess respectively included in the first semiconductor structure and the second semiconductor structure.

16. The gate-last high-K CMOS structure according to claim 15, wherein the buried-layer heavily doped region is formed in the channel only in the vicinity of the drain and the source respectively, under the gate recess respectively included in the first semiconductor structure and the second semiconductor structure.

17. The gate-last high-K CMOS structure according to claim 15, wherein the buried-layer heavily doped region is formed in the channel only in the vicinity of the drain, under the gate recess respectively included in the first semiconductor structure and the second semiconductor structure.
